(19) United States
(12) Patent Application Publication
(10) Pub. No.: US 2026/0231327 A1
(43) Pub. Date: Aug. 6, 2026

(54) CIRCUIT BOARD AND METHOD OF MANUFACTURING CIRCUIT BOARD

(71) Applicant: SAMSUNG ELECTRO-MECHANICS CO., LTD., Suwon-si (KR)

(72) Inventors: Yangje Lee, Suwon-si (KR); Sumin Seo, Suwon-si (KR)

(73) Assignee: SAMSUNG ELECTRO-MECHANICS CO., LTD., Suwon-si (KR)

(21) Appl. No.: 19/248,203

(22) Filed: Jun. 24, 2025

(30) Foreign Application Priority Data
Feb. 3, 2025 (KR) 10-2025-0013235

(51) Int. Cl. H05K 1/11; H05K 3/00; H05K 3/40

(52) U.S. Cl. CPC H05K 1/116; H05K 3/0094; H05K 3/4038; H05K 2201/09454; H05K 2201/0959; H05K 2201/10295

(57) ABSTRACT

A circuit board includes: an insulating layer having a via hole penetrating in a first direction; a through-via including a through portion configured to cover an inner wall of the via hole and having a hollow portion extending in the first direction, and a land portion extending from the through portion in a second direction perpendicular to the first direction; a circuit layer disposed on the insulating layer and spaced apart from the land portion of the through-via; and a plug including a plug body filling the hollow portion of the through-via and protruding outward from a surface of the insulating layer, and a plug head extending from the plug body in the second direction and disposed on the land portion.

### CROSS-REFERENCE TO RELATED APPLICATIONS

This application claims priority to and the benefit of Korean Patent Application No. 10-2025-0013235, filed on February 3, 2025, the disclosure of which is incorporated herein by reference in its entirety.

### BACKGROUND

### Technical Field

The present disclosure relates to a circuit board and a method of manufacturing the circuit board.

### Description of the Related Art

As electronic devices, particularly IT devices such as mobile phones, become smaller and lighter, high-density circuit design has become essential. Accordingly, circuit patterns applied to package PCBs (Printed Circuit Boards) are becoming finer, and the number of input/output integrated circuits is increasing. These technological changes require the development of key technologies for reducing circuit line width and spacing.

Conventional tenting processes have limitations in meeting these miniaturization requirements. Due to process constraints, degradation of circuit pattern uniformity and quality occurs during plating and etching processes, making it difficult to secure high-density design and stable power delivery characteristics. Against this background, new processes, namely MSAP (Modified Semi-Additive Process) and SAP (Semi-Additive Process), are gaining attention to overcome the limitations of conventional processes and improve miniaturization design rules.

### SUMMARY

Embodiments aim to provide a circuit board and a method of manufacturing the circuit board that solve the circuit pattern quality deterioration and uniformity problems occurring in conventional manufacturing methods, and overcome process constraints to meet high-density circuit design requirements.

However, the problems to be solved by the embodiments are not limited to the above-described problems and may be variously expanded in the scope of the technical concept included in the present disclosure.

According to an embodiment, a circuit board includes: an insulating layer having a via hole penetrating in a first direction; a through-via including a through portion configured to cover an inner wall of the via hole and having a hollow portion extending in the first direction, and a land portion extending from the through portion in a second direction perpendicular to the first direction; a circuit layer disposed on the insulating layer and spaced apart from the land portion of the through-via; and a plug including a plug body filling the hollow portion of the through-via and protruding outward from a surface of the insulating layer, and a plug head extending from the plug body in the second direction and disposed on the land portion.

The plug head may protrude outward from a surface of the land portion.

A diameter of the plug head in the second direction may be smaller than a diameter of the land portion in the second direction.

The land portion may have a step on a surface facing the plug head.

The step may have a side aligned with an edge of the plug head.

A number of metal layers in the through portion may be less than a number of metal layers in the land portion.

The through portion may include a seed layer pattern and an electroplating layer pattern sequentially stacked from an inner wall surface of the via hole, and the land portion may include a copper foil layer pattern, the seed layer pattern, and the electroplating layer pattern sequentially stacked on the insulating layer.

The seed layer pattern may be an electroless plating layer pattern.

Each of the circuit layer and the land portion may include a copper foil layer pattern, a seed layer pattern, and an electroplating layer pattern sequentially stacked on the insulating layer.

A number of metal layers in the through portion may be equal to a number of metal layers in the land portion.

The through portion may include a seed layer pattern and an electroplating layer pattern sequentially stacked from an inner wall surface of the via hole, and the land portion may include the seed layer pattern and the electroplating layer pattern sequentially stacked on the insulating layer.

The seed layer pattern may be an electroless plating layer pattern.

The seed layer pattern may be a sputtering layer pattern.

The circuit board may further include a primer resin layer between the insulating layer and the seed layer pattern.

According to an embodiment, a method of manufacturing a circuit board includes: forming a via hole penetrating a first insulating layer in a first direction; forming a first seed layer on a surface of the first insulating layer in which the via hole is formed; forming a first mask pattern on the first seed layer so as to expose the first seed layer of the via hole and an area surrounding the via hole; forming an electroplating layer pattern on the first seed layer exposed by the first mask pattern to form a through-via having a hollow portion penetrating in the first direction, and a land portion extending on the first insulating layer; forming a second mask pattern exposing the hollow portion of the through-via and at least a portion of the land portion of the through-via; forming a preliminary plug filling the hollow portion of the through-via; planarizing the preliminary plug and the second mask pattern; and forming a plug by removing the second mask pattern remaining after the planarization.

The method of manufacturing the circuit board may further include forming a second insulating layer on the first insulating layer to embed the land portion of the through-via and the plug.

The forming of the preliminary plug may include filling the hollow portion of the through-via with a non-conductive material.

The method of manufacturing the circuit board may further include forming a copper foil layer on the first insulating layer, and the forming of the first seed layer may include forming the first seed layer on the copper foil layer.

The forming of the first seed layer may include forming the first seed layer on the first insulating layer through sputtering or electroless plating.

The method of manufacturing the circuit board may further include forming a primer resin layer on the first insulating layer.

The embodiments may effectively solve circuit pattern uniformity degradation and quality issues occurring in conventional processes. This enables finer circuit line widths and spacing for high-density design, significantly improving the performance of electronic devices, particularly miniaturized IT devices.

Furthermore, the embodiments may improve power integrity characteristics by significantly enhancing manufacturing process tolerances and reliability. This means they may be widely applied in various electronic device environments requiring high performance and stability.

Consequently, the embodiments may contribute to increasing the efficiency of circuit board manufacturing processes, meeting miniaturization design requirements, and achieving thin, lightweight, and highly integrated electronic devices.

### BRIEF DESCRIPTION OF THE DRAWINGS

FIG. 1 is a cross-sectional view schematically showing a structure of a circuit board according to an embodiment. FIG. 2 is a cross-sectional view showing an enlarged portion A of the circuit board shown in FIG. 1.

FIGS. 3 to 12 are process cross-sectional views for explaining a method of manufacturing a circuit board according to an embodiment.

FIGS. 13 to 15 are process cross-sectional views for explaining a method of manufacturing a circuit board according to another embodiment.

FIG. 16 is a cross-sectional view schematically showing a structure of a circuit board according to still another embodiment.

FIGS. 17 to 24 are process cross-sectional views for explaining a method of manufacturing a circuit board according to still another embodiment.

FIG. 25 is a cross-sectional view schematically showing a structure of a circuit board according to still another embodiment.

FIGS. 26 to 28 are process cross-sectional views for explaining a method of manufacturing a circuit board according to still another embodiment.

### DETAILED DESCRIPTION

Hereinafter, embodiments of the present disclosure will be described in detail with reference to the accompanying drawings so that those skilled in the art to which the present disclosure pertains may easily carry out the embodiments. In the drawings, parts irrelevant to the description have been omitted for clarity of the disclosure, and like reference numerals designate like or similar components throughout the specification.

Some components in the accompanying drawings may be exaggerated, omitted, or schematically illustrated, and the size of each component does not fully reflect its actual size. Also, the accompanying drawings are for helping understanding of the embodiments disclosed in this specification, and the technical concept disclosed in this specification is not limited thereby and should be understood to include all modifications, equivalents, or alternatives falling in the spirit and technical scope of the disclosure.

The terms including ordinal numbers such as "first," "second," and the like used in this specification are used only as identifiers to distinguish various components and do not limit the importance or order of the corresponding components.

When one part is described as being "on" another part, this includes not only direct contact but also cases where other parts intervene between them. However, the expression "directly on" means a direct contact relationship without other parts intervening between them. Also, such positional relationships are independent of the direction of gravity.

The terms "include" or "have" used in this specification indicate the presence of features, numbers, steps, operations, components, parts, or combinations thereof described in the specification. This does not exclude the possibility that other features, numbers, steps, operations, components, parts, or combinations thereof may additionally exist. Therefore, unless specifically stated otherwise, when one part "includes" a certain component, it means that other components may be added.

In this specification, "plan view" means a view of an object seen from above, and "cross-sectional view" means a view of a vertical cross-section of an object seen from the side.

In this specification, the expression "connected" includes various forms of connection between two or more components. This includes not only direct connection but also indirect connection through other components, both physical and electrical connections, and includes cases where components form an integral unit even if referred to by different names according to their position or function.

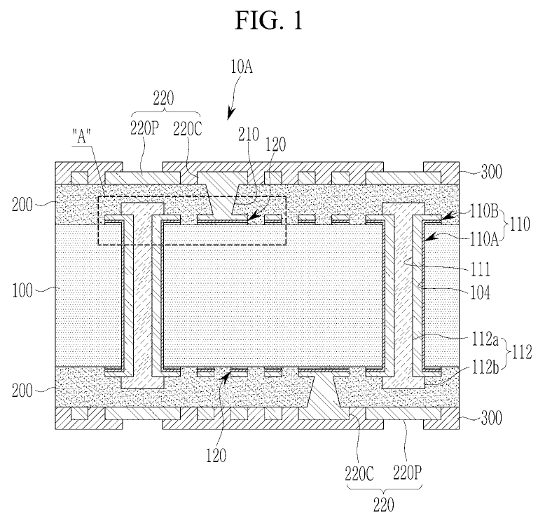

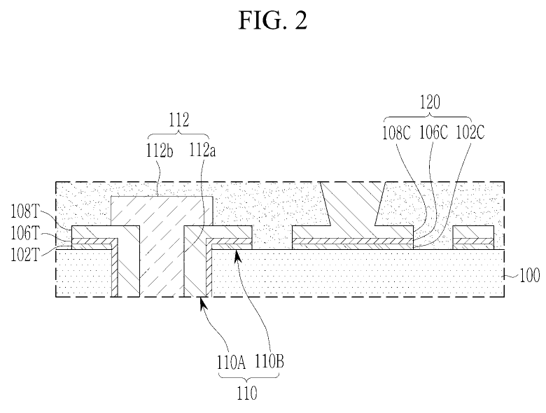

FIG. 1 is a cross-sectional view schematically showing a structure of a circuit board according to an embodiment. FIG. 2 is a cross-sectional view showing an enlarged portion A of the circuit board shown in FIG. 1.

Referring to FIG. 1, a circuit board 10A according to an embodiment may include a first insulating layer 100 provided as a core layer. A first circuit layer 120 may be disposed on both surfaces of the first insulating layer 100. A second insulating layer 200 may be disposed on the first insulating layer 100 to cover the first circuit layer 120. A second circuit layer 220 including connection pads 220P and circuit wiring 220C may be disposed on the second insulating layer 200. The second circuit layer 220 may be connected to the first circuit layer 120 through a build-up via 210 penetrating the second insulating layer 200.

A protective layer 300 may be disposed on the second insulating layer 200. The protective layer 300 may protect internal components from external physical and chemical damage. The protective layer 300 covers one surface of the second insulating layer 200 and may expose at least a portion of the connection pad 220P. The protective layer 300 may be made of a photosensitive resin, for example, a solder resist layer.

The first insulating layer 100 and the second insulating layer 200 may include insulating materials. The insulating materials may include thermosetting resins such as epoxy resin, thermoplastic resins such as polyimide, or materials including inorganic fillers, organic fillers, and/or glass fibers (Glass Fiber, Glass Cloth, and/or Glass Fabric) with these resins, and may be photosensitive and/or non-photosensitive materials. For example, insulating materials such as SR (Solder Resist), ABF (Ajinomoto Build-up Film), FR-4, BT (Bismaleimide Triazine), insulator of RCC (Resin Coated Copper), insulator of CCL (Copper Clad Laminate) may be used, but are not limited thereto and may include other polymer materials. For example, prepreg may be used, but is not limited thereto. Also, while the first insulating layer 100 is shown as a single layer in FIG. 1, it is not limited thereto, and may be formed of multiple thin layers stacked together.

Each of the first circuit layer 120 and the second circuit layer 220 may transmit signals inside the circuit board 10A. Metal materials may be used as materials for each of the first circuit layer 120 and the second circuit layer 220. The metal materials may include copper (Cu), aluminum (Al), silver (Ag), tin (Sn), gold (Au), nickel (Ni), lead (Pb), titanium (Ti), or alloys thereof. Each of the first circuit layer 120 and the second circuit layer 220 may perform various functions according to design patterns such as ground patterns, power patterns, signal patterns, and the like. These patterns may each have the form of a line, plane, or pad. In the case of a circuit layer located at the outermost layer among multiple circuit layers, it may function as a connection pad for connection with other substrates or components.

The first insulating layer 100 may have a via hole 104 penetrating in a first direction which is a stacking direction. A through-via 110 may extend filling the via hole 104, and the through-via 110 may have a hollow portion 111 penetrating in the first direction. The through-via 110 may include a through portion 110A extending in the first direction to cover the inner wall of the via hole 104, and a land portion 110B extending in a second direction perpendicular to the first direction from both ends of the through portion 110A. The land portion 110B of the through-via 110 may be positioned on the first insulating layer 100 in the same layer as the first circuit layer 120 and may function to connect the through-via 110 to the first circuit layer 120.

Metal materials may be used as materials for each of the through-via 110 and the build-up via 210. The metal materials may include copper (Cu), aluminum (Al), silver (Ag), tin (Sn), gold (Au), nickel (Ni), lead (Pb), titanium (Ti), or alloys thereof. Each of the through-via 110 and the build-up via 210 may include signal vias, ground vias, power vias, and the like, according to the design pattern.

The plug 112 may fill the hollow portion 111 of the through-via 110 and protrude outward from the surface of the first insulating layer 100. The plug 112 may include insulating plugging ink. The plug 112 may prevent oxidation of the through-via 110 by filling empty space inside the via hole 104. The plug 112 may include a plug body 112a filling the hollow portion 111 of the through-via 110 and extending to the outer surface of the first insulating layer 100, and a plug head 112b extending from both ends of the plug body 112a in the second direction perpendicular to the first direction and positioned above the land portion 110B of the through-via 110. Here, a cross-sectional diameter of the plug head 112b in the second direction may be larger than a cross-sectional diameter of the plug body 112a in the second direction. The cross-sectional diameters may be measured by optical microscope or a scanning electron microscope. Other methods and/or tools appreciated by one of ordinary skill in the art, even if not described in the present disclosure, may also be used. The hollow portion 111 may be formed along the inner surface of the through portion 110A, and thus the through portion 110A may be positioned to surround the plug body 112a.

Hereinafter, referring additionally to FIG. 2, a detailed layer structure of the first circuit layer 120 and the through-via 110 of the circuit board 10A according to an embodiment will be described in more detail.

Referring to FIGS. 1 and 2, the first circuit layer 120 may include a plurality of stacked metal layers, and may include a copper foil layer pattern 102C, a seed layer pattern 106C, and an electroplating layer pattern 108C sequentially stacked in the first direction on the insulating layer 100.

The through portion 110A of the through-via 110 may include a seed layer pattern 106T and an electroplating layer pattern 108T stacked from the inner wall surface of the via hole 104 toward the center. The land portion 110B of the through-via 110 may include a copper foil layer pattern 102T, a seed layer pattern 106T, and an electroplating layer pattern 108T sequentially stacked in the first direction on the first insulating layer 100. That is, the land portion 110B of the through-via 110 may be formed by stacking the seed layer pattern 106T on the copper foil layer pattern 102T and stacking the electroplating layer pattern 108T on the seed layer pattern 106T.

Here, the seed layer patterns 106C and 106T of each of the first circuit layer 120 and the through-via 110 may be metal layers formed by electroless plating, for example, copper (Cu) layers, and the electroplating layer patterns 108C and 108T may be metal layers formed on the seed layer patterns 106C and 106T by electroplating, for example, copper (Cu) layers.

Hereinafter, a method of manufacturing the circuit board 10A according to an embodiment will be described with reference to FIGS. 1 and 3 to 12.

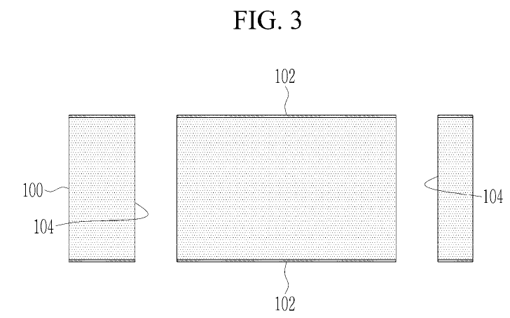

FIGS. 3 to 12 are process cross-sectional views for explaining a method of manufacturing a circuit board according to an embodiment.

Referring to FIG. 3, a first insulating layer 100 having copper foil layers 102 formed on both surfaces may be prepared. The copper foil layers 102 may be formed by laminating and pressing copper foils on both surfaces of the first insulating layer 100. Via holes 104 penetrating the first insulating layer 100 and the copper foil layers 102 may be formed. The via holes 104 may be formed in plurality by laser, mechanical drilling, and the like.

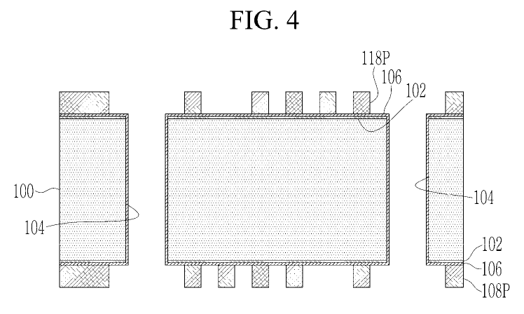

Referring to FIG. 4, a seed layer 106 may be formed on the surface of the first insulating layer 100 in which the via holes 104 are formed. The seed layer 106 may be formed on the copper foil layer 102 and on the inner walls of the via holes 104. The seed layer 106 may be formed as a copper (Cu) layer through electroless plating. A first mask pattern 118P exposing the seed layer 106 of the via holes 104 and their surroundings may be formed on the seed layer 106. The first mask pattern 118P may expose an area positioned along the edges of the via holes 104 on the seed layer 106. Also, the first mask pattern 118P may expose the seed layer 106 in areas where circuit wiring will be formed in the future. The first mask pattern 118P may be patterned by exposing and developing a photosensitive dry film.

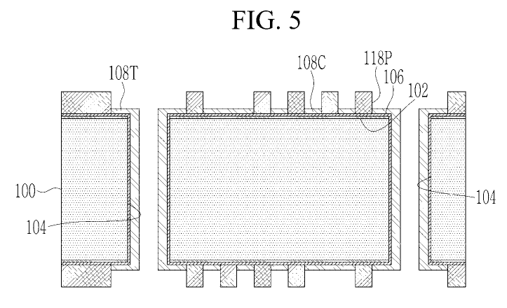

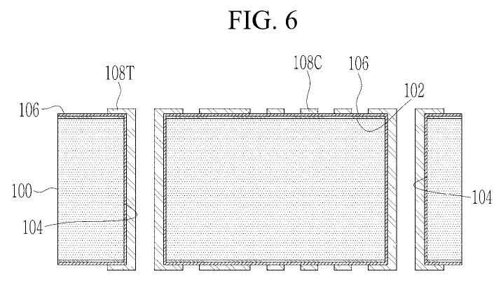

Referring to FIGS. 5 and 6, an electroplating layer pattern 108T may be formed by electroplating on the seed layer 106 exposed around the via holes 104 and their surroundings by the first mask pattern 118P, and the electroplating layer pattern 108T may be made of copper (Cu). In areas other than around the via holes 104 of the first insulating layer 100, an electroplating layer pattern 108C for forming the first circuit layer 120 may be formed on the exposed seed layer 106 using the first mask pattern 118P as a plating mask. This electroplating layer pattern 108C may be formed as a copper (Cu) layer. Subsequently, the first mask pattern 118P may be stripped and removed.

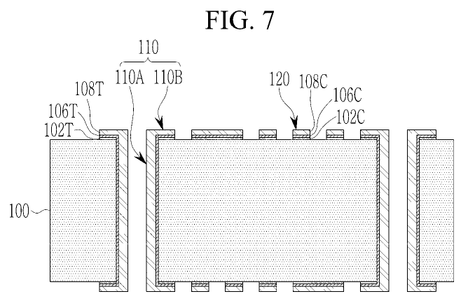

Referring to FIG. 7, after removing the first mask pattern 118P, the exposed seed layer 106 and the underlying copper foil layer 102 may be removed through flash etching to form the first circuit layer 120 and the through-via 110. The first circuit layer 120 may be formed on the first insulating layer 100 to include the copper foil layer pattern 102C, the seed layer pattern 106C, and the electroplating layer pattern 108C. The through-via 110 may include the through portion 110A on the inner wall of the via hole 104, and the land portion 110B connected to the through portion 110A and extending onto the top and bottom surfaces of the first insulating layer 100. The through portion 110A of the through-via 110 may include the seed layer pattern 106T and the electroplating layer pattern 108T stacked on the inner wall surface of the via hole 104. The land portion 110B of the through-via 110 may include the copper foil layer pattern 102T, the seed layer pattern 106T, and the electroplating layer pattern 108T stacked on the first insulating layer 100.

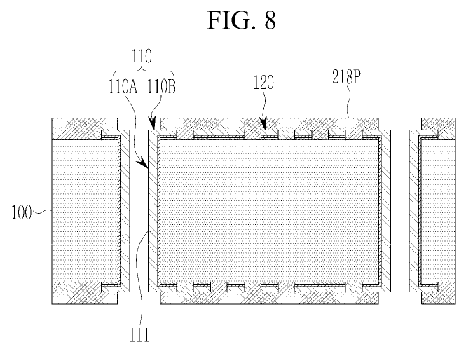

Referring to FIG. 8, a second mask pattern 218P may be formed on the first insulating layer 100 on which the first circuit layer 120 is formed. The second mask pattern 218P may cover a portion of the land portion 110B of the through-via 110 and expose a portion of the land portion 110B positioned along the hollow portion 111 of the through-via 110 and its edges. The second mask pattern 218P may be patterned by exposing and developing a photosensitive dry film.

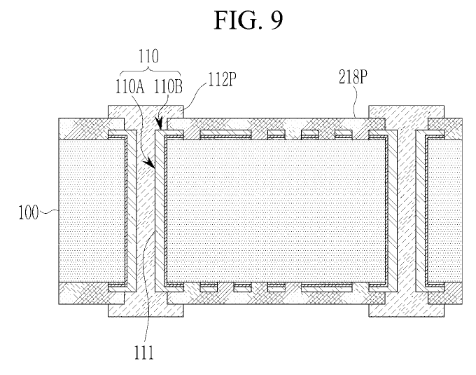

Referring to FIG. 9, a preliminary plug 112P may be formed to fill the interior of the hollow portion 111 of the through-via 110 and extend stepwise over the exposed land portion 110B and the second mask pattern 218P. That is, the preliminary plug 112P may be partially positioned on the land portion 110B exposed by the second mask pattern 218P and may be positioned along the opened edges of the second mask pattern 218P. The preliminary plug 112P may be formed by printing insulating ink.

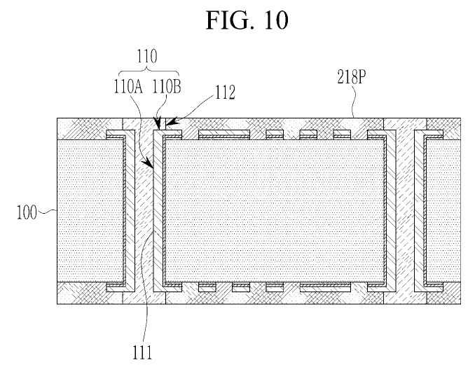

Referring to FIG. 10, the portion of the preliminary plug 112P formed on the second mask pattern 218P and the second mask pattern 218P may be polished together to planarize their surfaces. During this process, the portion of the preliminary plug 112P extending over the second mask pattern 218P may be removed to become the plug 112. Also, the thickness of the plug 112 portion positioned on the land portion 110B and the second mask pattern 218P may become smaller than before planarization, and the surfaces of the plug 112 and the second mask pattern 218P may be positioned substantially in the same plane. A portion of the plug 112 may be surrounded by the through portion 110A of the through-via 110 and may be formed including non-conductive material.

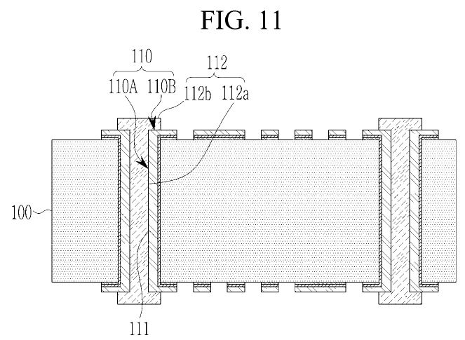

Referring to FIG. 11, when the remaining second mask pattern 218P is stripped and removed, a plug 112 may be formed filling the hollow portion 111 of the through-via 110 and protruding and extending over the land portion 110B. Therefore, the plug 112 may include a plug body 112a filling the hollow portion 111 of the through-via 110 penetrating in the first direction and protruding outward from the first insulating layer 100, and a plug head 112b extending from this plug body 112a in the second direction perpendicular to the first direction and disposed on the land portion 110B.

The land portion 110B of the through-via 110 may include the copper foil layer pattern 102T, seed layer pattern 106T, and electroplating layer pattern 108T sequentially stacked on the first insulating layer 100, and at least a portion of the head 112b of the plug 112 may be positioned on the electroplating layer pattern 108T of the land portion 110B.

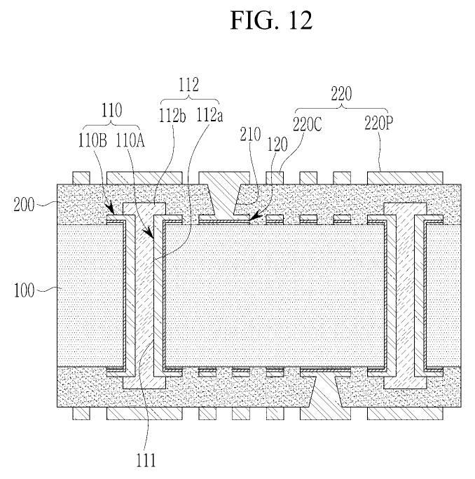

Referring to FIG. 12, a second insulating layer 200 may be formed on the first insulating layer 100 to embed the first circuit layer 120, land portion 110B of the through-via 110, and plug head 112b. Also, connection pads 220P and circuit wiring 220C of the second circuit layer 220 may be formed on the second insulating layer 200. Additionally, build-up vias 210 may be formed penetrating the second insulating layer 200 to connect the first circuit layer 120 and the circuit wiring 220C of the second circuit layer 220. The connection pads 220P, circuit wiring 220C, and build-up vias 210 of the second circuit layer 220 may be formed by performing conventional wiring formation methods, for example, subtractive process, AP (Additive Process), SAP (Semi Additive Process), or MSAP (Modified Semi Additive Process).

Referring to FIGS. 12 and 1 together, a protective layer 300 exposing a portion of the connection pads 220P may be formed on the second insulating layer 200 on which the connection pads 220P and circuit wiring 220C of the second circuit layer 220 are formed. The protective layer 300 may be a solder resist layer formed by exposing and developing photosensitive resin.

According to the method of manufacturing a circuit board according to an embodiment, because the through-via and plug are formed after forming a mask pattern on the copper foil layer and seed layer laminated on the insulating layer, the through-via may be formed more finely and precisely compared to when it is formed by plating the entire top surface of the insulating layer and then etching.

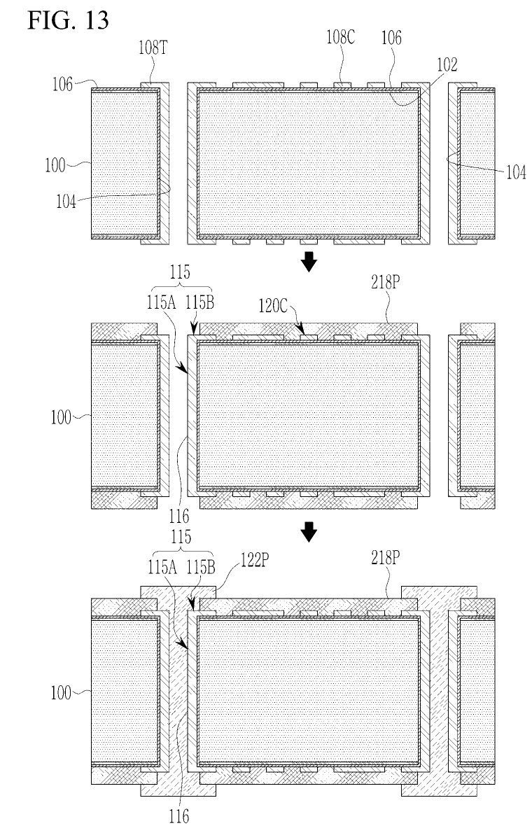

FIGS. 13 to 15 are process cross-sectional views for explaining a method of manufacturing a circuit board according to another embodiment.

In the method of manufacturing the circuit board described with reference to FIGS. 1 to 12, the first circuit layer 120 and the through-via 110 are formed to be distinguished from each other before forming the plug 112. That is, the seed layer 106 and copper foil layer 102 are patterned through flash etching before filling the interior of the hollow portion 111 of the through-via 110 with the preliminary plug 112P. In contrast, in the method of manufacturing the circuit board according to this embodiment, the plug 122 may be formed before flash etching for patterning the seed layer 106 and copper foil layer 102, and the seed layer 106 and copper foil layer 102 may be patterned by flash etching together with the thus-formed plug 122.

Referring to FIG. 13, via holes 104 may be formed penetrating through the first insulating layer 100 having copper foil layers 102 formed on both surfaces, and a seed layer 106 may be formed by electroless plating on the copper foil layers 102 and on the inner walls of the via holes 104. An electroplating layer may be formed by performing electroplating after exposing the seed layer 106 of the via holes 104 and their surroundings, and the area where the first circuit layer 120 will be formed, using a first mask pattern.

The electroplating layer formed on the seed layer 106 on the inner walls of the via holes 104 may constitute the through-via 115 by connecting with the electroplating layer around the via holes 104. Specifically, the electroplating layer on the inner walls of the via holes 104 may form the through portion 115A of the through-via 115, and the electroplating layer around the via holes 104 may form the land portion 115B of the through-via 115 as the electroplating layer pattern 108T. Also, an electroplating layer pattern 108C may be formed in the area where the first circuit layer 120 will be formed.

Then, a second mask pattern 218P may be formed on the seed layer 106 and electroplating layer patterns 108T and 108C. The second mask pattern 218P may cover a portion of the electroplating layer pattern 108T that will constitute the land portion 115B of the through-via 115, and may expose a portion of the land portion 115B positioned along the hollow portion 116 of the through-via 115 and its edges. The second mask pattern 218P may be patterned by exposing and developing a photosensitive dry film.

Then, a preliminary plug 122P may be formed filling the interior of the hollow portion 116 of the through-via 115 and extending stepwise over the exposed land portion 115B and the second mask pattern 218P. That is, the preliminary plug 122P may be partially positioned on the land portion 115B exposed by the second mask pattern 218P and may be positioned along the opened edges of the second mask pattern 218P. The preliminary plug 122P may be formed by printing insulating ink.

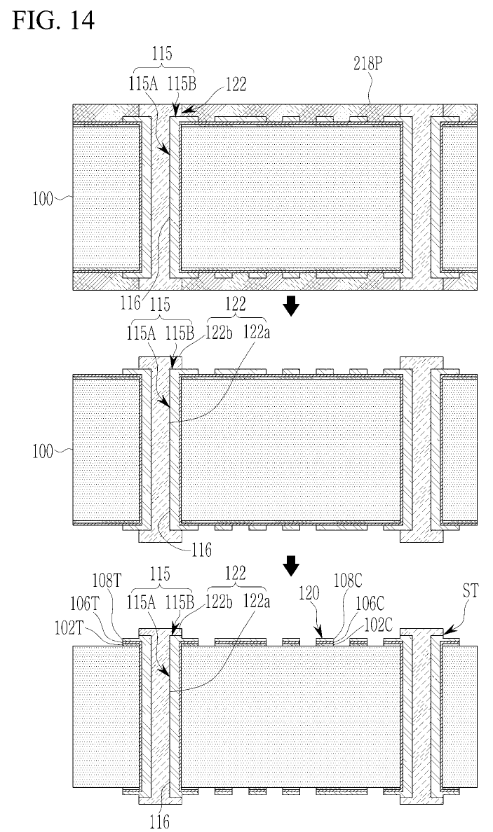

Referring to FIG. 14, the portion of the preliminary plug 122P formed on the second mask pattern 218P and the second mask pattern 218P may be polished together to planarize their surfaces. During this process, the portion of the preliminary plug 122P extending over the second mask pattern 218P may be removed to become the plug 122. Also, the thickness of the plug 122 portion positioned on the land portion 115B and the second mask pattern 218P may become smaller than before planarization, and the surfaces of the plug 122 and the second mask pattern 218P may be positioned substantially in the same plane. A portion of the plug 122 may be surrounded by the through portion 115A of the through-via 115 and may be formed including non-conductive material.

Then, when the remaining second mask pattern 218P is stripped and removed, a plug 122 may be formed filling the hollow portion 116 of the through-via 115 and protruding and extending over the land portion 115B. Therefore, the plug 122 may include a plug body 122a filling the hollow portion 116 of the through-via 115 penetrating in the first direction and protruding outward from the first insulating layer 100, and a plug head 122b extending from this plug body 122a in the second direction perpendicular to the first direction and disposed on the land portion 115B.

Then, after removing the second mask pattern 218P, the first circuit layer 120 and the through-via 115 may be formed by removing the exposed seed layer 106 and copper foil layer 102 through flash etching. The first circuit layer 120 may be formed on the first insulating layer 100 to include the seed layer pattern 126C and the electroplating layer pattern 128C. The through portion 115A of the through-via 115 may include the seed layer pattern 106T and the electroplating layer pattern 108T stacked on the inner wall surface of the via hole 104. The land portion 115B of the through-via 115 may include the seed layer pattern 106T and the electroplating layer pattern 108T stacked on the first insulating layer 100.

At least a portion of the plug head 122b may be positioned on the electroplating layer pattern 108T of the land portion 115B. During the flash etching process, a portion of the electroplating layer pattern 108T constituting the land portion 115B of the through-via 115 is exposed to the etching solution, but the portion of the electroplating layer pattern 108T covered by the plug head 122b may not be exposed to the etching solution. Therefore, the exposed portion of the electroplating layer pattern 108T may be etched to become lower than the unexposed portion. As a result, the electroplating layer pattern 108T of the land portion 115B may have a step difference ST on the surface facing the plug head 122b, and this step difference ST may have a side aligned with the edge of the plug head 122b.

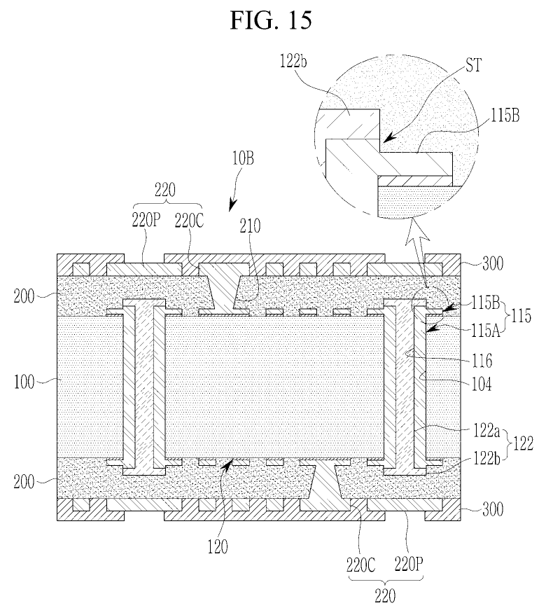

Referring to FIG. 15, a second insulating layer 200 may be formed on the first insulating layer 100 to embed the first circuit layer 120, land portion 115B of the through-via 115, and plug head 122b. Also, a second circuit layer 220 including connection pads 220P and circuit wiring 220C may be formed on the second insulating layer 200. Additionally, build-up vias 210 may be formed penetrating the second insulating layer 200 to connect the first circuit layer 120 and the second circuit layer 220. The second circuit layer 220 and build-up vias 210 may be formed by performing conventional wiring formation methods, for example, subtractive process, AP (Additive Process), SAP (Semi Additive Process), or MSAP (Modified Semi Additive Process).

A protective layer 300 exposing a portion of the connection pads 220P may be formed on the second insulating layer 200 on which the connection pads 220P and circuit wiring 220C of the second circuit layer 220 are formed. The protective layer 300 may be a solder resist layer formed by exposing and developing photosensitive resin. Thus, the circuit board 10B according to this embodiment may be completed.

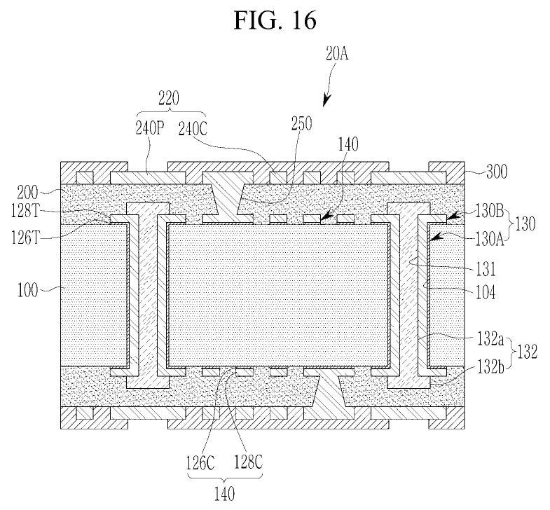

FIG. 16 is a cross-sectional view schematically showing a structure of a circuit board according to still another embodiment.

Referring to FIG. 16, a circuit board 20A according to an embodiment may include a first insulating layer 100 provided as a core layer. A first circuit layer 140 may be disposed on both surfaces of the first insulating layer 100. A second insulating layer 200 may be disposed on the first insulating layer 100 to cover the first circuit layer 140. A second circuit layer 240 including connection pads 240P and circuit wiring 240C may be disposed on the second insulating layer 200. The second circuit layer 240 may be connected to the first circuit layer 140 through a build-up via 250 penetrating the second insulating layer 200.

A protective layer 300 may be disposed on the second insulating layer 200. The protective layer 300 may protect internal components from external physical and chemical damage. The protective layer 300 covers one surface of the second insulating layer 200 and may expose at least a portion of the connection pads 240P. The protective layer 300 may be made of a photosensitive resin, for example, a solder resist layer.

The first insulating layer 100 and the second insulating layer 200 may include insulating materials. The insulating materials may include thermosetting resins such as epoxy resin, thermoplastic resins such as polyimide, or materials including inorganic fillers, organic fillers, and/or glass fibers (Glass Fiber, Glass Cloth, and/or Glass Fabric) with these resins, and may be photosensitive and/or non-photosensitive materials. For example, insulating materials such as SR (Solder Resist), ABF (Ajinomoto Build-up Film), FR-4, BT (Bismaleimide Triazine), insulator of RCC (Resin Coated Copper), insulator of CCL (Copper Clad Laminate) may be used, but are not limited thereto and may include other polymer materials. For example, prepreg may be used, but is not limited thereto. Also, while the first insulating layer 100 is shown as a single layer in FIG. 16, it is not limited thereto, and may be formed of multiple thin layers stacked together.

Each of the first circuit layer 140 and the second circuit layer 240 may transmit signals inside the circuit board 20A. Metal materials may be used as materials for each of the first circuit layer 140 and the second circuit layer 240. The metal materials may include copper (Cu), aluminum (Al), silver (Ag), tin (Sn), gold (Au), nickel (Ni), lead (Pb), titanium (Ti), or alloys thereof. Each of the first circuit layer 140 and the second circuit layer 240 may perform various functions according to design patterns such as ground patterns, power patterns, signal patterns, and the like. These patterns may each have the form of a line, plane, or pad. In the case of a circuit layer located at the outermost layer among multiple circuit layers, it may function as a connection pad for connection with other substrates or components.

The first insulating layer 100 may have a via hole 104 penetrating in a first direction which is a stacking direction. A through-via 130 may extend filling the via hole 104, and the through-via 130 may have a hollow portion 131 penetrating in the first direction. The through-via 130 may include a through portion 130A extending in the first direction to cover the inner wall of the via hole 104, and a land portion 130B extending in a second direction perpendicular to the first direction from both ends of the through portion 130A. The land portion 130B of the through-via 130 may be positioned on the first insulating layer 100 in the same layer as the first circuit layer 140 and may function to connect the through-via 130 to the first circuit layer 140.

Metal materials may be used as materials for each of the through-via 130 and the build-up via 250. The metal materials may include copper (Cu), aluminum (Al), silver (Ag), tin (Sn), gold (Au), nickel (Ni), lead (Pb), titanium (Ti), or alloys thereof. Each of the through-via 130 and the build-up via 250 may include signal vias, ground vias, power vias, and the like, according to the design pattern.

The plug 132 may fill the hollow portion 131 of the through-via 130 and protrude outward from the surface of the first insulating layer 100. The plug 132 may include insulating plugging ink. The plug 132 may prevent oxidation of the through-via 130 by filling empty space inside the via hole 104. The plug 132 may include a plug body 132a filling the hollow portion 131 of the through-via 130 and extending to the outer surface of the first insulating layer 100, and a plug head 132b extending from both ends of the plug body 132a in the second direction perpendicular to the first direction and positioned above the land portion 130B of the through-via 130. Here, a cross-sectional diameter of the plug head 132b in the second direction may be larger than a cross-sectional diameter of the plug body 132a in the second direction. The hollow portion 131 may be formed along the inner surface of the through portion 130A, and thus the through portion 130A may be positioned to surround the plug body 132a.

The first circuit layer 140 may include a plurality of stacked metal layers, and may include a seed layer pattern 126C and an electroplating layer pattern 128C sequentially stacked in the first direction on the insulating layer 100.

The through portion 130A of the through-via 130 may include a seed layer pattern 126T and an electroplating layer pattern 128T stacked from the inner wall surface of the via hole 104 toward the center. The land portion 130B of the through-via 130 may include a seed layer pattern 126T and an electroplating layer pattern 128T sequentially stacked in the first direction on the first insulating layer 100. Here, the seed layer patterns 126C and 126T of each of the first circuit layer 140 and the through-via 130 may be metal layers formed by electroless plating, for example, copper (Cu) layers, and the electroplating layer patterns 128C and 128T may be metal layers formed on the seed layer pattern 126T by electroplating, for example, copper (Cu) layers.

Hereinafter, a method of manufacturing the circuit board 20A shown in FIG. 16 will be described with reference to FIGS. 16 and 17 to 24.

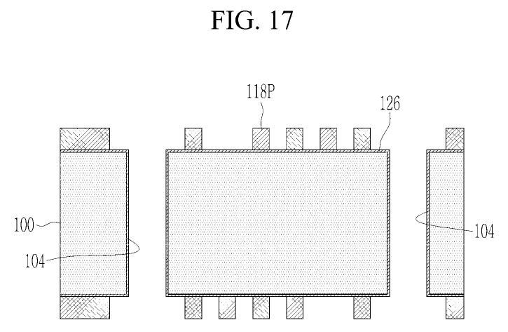

FIGS. 17 to 24 are process cross-sectional views for explaining a method of manufacturing a circuit board according to still another embodiment.

Referring to FIG. 17, via holes 104 may be formed penetrating the first insulating layer 100, and a seed layer 126 may be formed on the surface of the first insulating layer 100 in which the via holes 104 are formed. The via holes 104 may be formed in plurality by laser, mechanical drilling, and the like. The seed layer 126 may be formed on the first insulating layer 100 and on the inner walls of the via holes 104. The seed layer 126 may be formed as a copper (Cu) layer through sputtering or electroless plating.

A first mask pattern 118P exposing the seed layer 126 of the via holes 104 and their surroundings may be formed on the seed layer 126. The first mask pattern 118P may expose an area positioned along the edges of the via holes 104 on the seed layer 126. Also, the first mask pattern 118P may expose the seed layer 126 in areas where circuit wiring will be formed in the future. The first mask pattern 118P may be patterned by exposing and developing a photosensitive dry film.

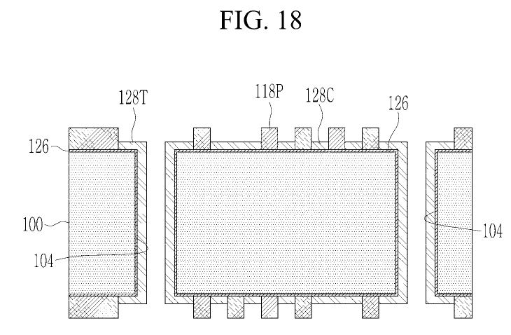

Referring to FIG. 18, an electroplating layer pattern 128T may be formed by electroplating on the seed layer 106 exposed around the via holes 104 and their surroundings by the first mask pattern 118P, and the electroplating layer pattern 128T may be made of copper (Cu). In areas other than around the via holes 104 of the first insulating layer 100, an electroplating layer pattern 128C for forming the first circuit layer 140 may be formed on the exposed seed layer 126 using the first mask pattern 118P as a plating mask. This electroplating layer pattern 128C may be formed as a copper (Cu) layer. Subsequently, the first mask pattern 118P may be stripped and removed.

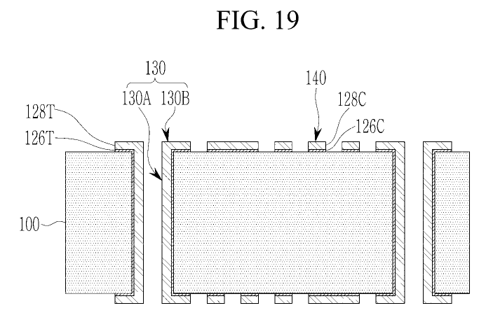

Referring to FIG. 19, after removing the first mask pattern 118P, the first circuit layer 140 and the through-via 130 may be formed by removing the exposed seed layer 126 through quick etching. The first circuit layer 140 may be formed on the first insulating layer 100 to include the seed layer pattern 126C and the electroplating layer pattern 128C. The through portion 130A of the through-via 130 may include the seed layer pattern 126T and the electroplating layer pattern 128T stacked on the inner wall surface of the via hole 104. The land portion 130B of the through-via 130 may include the seed layer pattern 126T and the electroplating layer pattern 128T stacked on the first insulating layer 100.

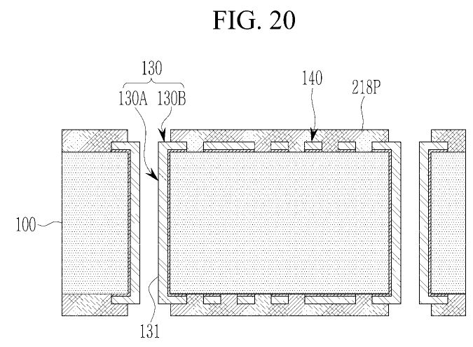

Referring to FIG. 20, a second mask pattern 218P may be formed on the first insulating layer 100 on which the first circuit layer 140 is formed. The second mask pattern 218P may cover a portion of the land portion 130B of the through-via 130 and expose a portion of the land portion 130B positioned along the hollow portion 131 of the through-via 130 and its edges. The second mask pattern 218P may be patterned by exposing and developing a photosensitive dry film.

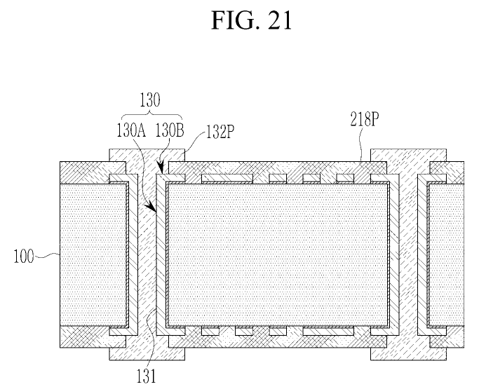

Referring to FIG. 21, a preliminary plug 132P may be formed filling the interior of the hollow portion 131 of the through-via 130 and extending stepwise over the exposed land portion 130B and the second mask pattern 218P. That is, the preliminary plug 132P may be partially positioned on the land portion 130B exposed by the second mask pattern 218P and may be positioned along the opened edges of the second mask pattern 218P. The preliminary plug 132P may be formed by printing insulating ink.

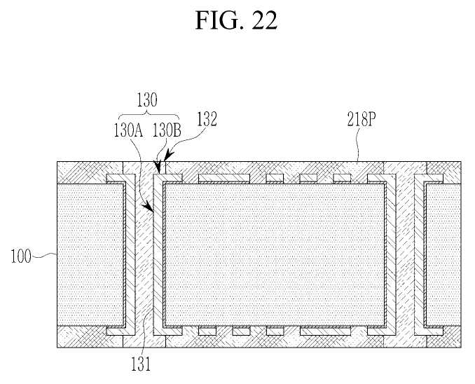

Referring to FIG. 22, the portion of the preliminary plug 132P formed on the second mask pattern 218P and the second mask pattern 218P may be polished together to planarize their surfaces. During this process, the portion of the preliminary plug 132P extending over the second mask pattern 218P may be removed to become the plug 132. Also, the thickness of the plug 132 portion positioned on the land portion 130B and the second mask pattern 218P may become smaller than before planarization, and the surfaces of the plug 132 and the second mask pattern 218P may be positioned substantially in the same plane. A portion of the plug 132 may be surrounded by the through portion 130A of the through-via 130 and may be formed including non-conductive material.

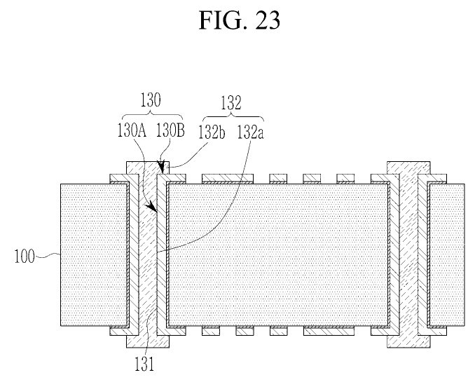

Referring to FIG. 23, when the remaining second mask pattern 218P is stripped and removed, a plug 132 may be formed filling the hollow portion 131 of the through-via 130 and protruding and extending over the land portion 130B. Therefore, the plug 132 may include a plug body 132a filling the hollow portion 131 of the through-via 130 penetrating in the first direction and protruding outward from the first insulating layer 100, and a plug head 132b extending from this plug body 132a in the second direction perpendicular to the first direction and disposed on the land portion 130B.

The land portion 130B of the through-via 130 may include a seed layer pattern 126T and an electroplating layer pattern 128T sequentially stacked on the first insulating layer 100, and at least a portion of the head 132b of the plug 132 may be positioned on the electroplating layer pattern 128T of the land portion 130B.

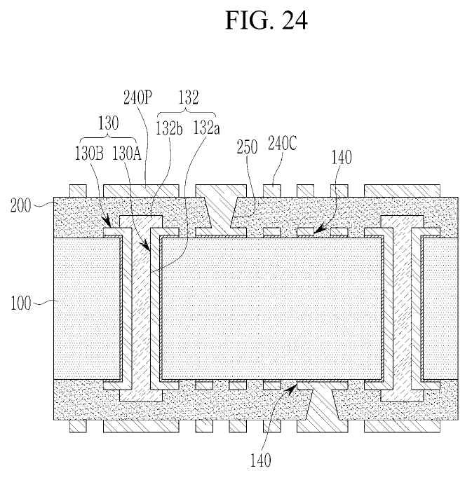

Referring to FIG. 24, a second insulating layer 200 may be formed on the first insulating layer 100 to embed the first circuit layer 140, land portion 130B of the through-via 130, and plug head 132b. Also, a second circuit layer 240 including connection pads 240P and circuit wiring 240C may be formed on the second insulating layer 200. Additionally, build-up vias 250 may be formed penetrating the second insulating layer 200 to connect the first circuit layer 140 and the second circuit layer 240. The second circuit layer 240 and build-up vias 250 may be formed by performing conventional wiring formation methods, for example, subtractive process, AP (Additive Process), SAP (Semi Additive Process), or MSAP (Modified Semi Additive Process).

Referring to FIGS. 24 and 16 together, a protective layer 300 exposing a portion of the connection pads 240P may be formed on the second insulating layer 200 on which the connection pads 240P and circuit wiring 240C of the second circuit layer 220 are formed. The protective layer 300 may be a solder resist layer formed by exposing and developing photosensitive resin.

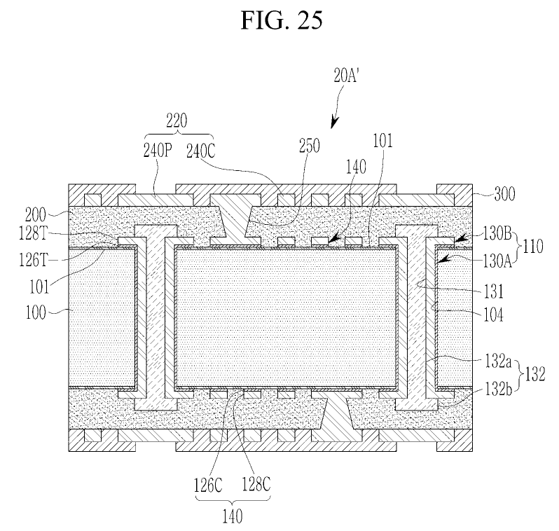

FIG. 25 is a cross-sectional view schematically showing a structure of a circuit board 20A' according to still another embodiment.

In the method of manufacturing the circuit board described with reference to FIGS. 17 to 24, before forming the seed layer 126, a primer resin layer 101 may be coated on the first insulating layer 100, and a primer copper foil CCL (Copper Clad Laminate) may be manufactured and used by laminating copper foil on the primer resin layer 101. The copper foil on the surface of the CCL may be removed by etching before forming the seed layer 126, and during this process, the primer resin layer 101 may be exposed. A palladium catalyst may be adsorbed on the surface of the thus-exposed primer resin layer 101, and the seed layer 126 may be formed through sputtering or electroless plating on the surface where the catalyst is adsorbed. Therefore, the primer resin layer 101 may be maintained during subsequent circuit board manufacturing processes.

Referring to FIG. 25, in the circuit board 20A' according to this embodiment, the first circuit layer 140, through-via 130, and second circuit layer 240 may be formed while maintaining the primer resin layer 101 on the first insulating layer 100.

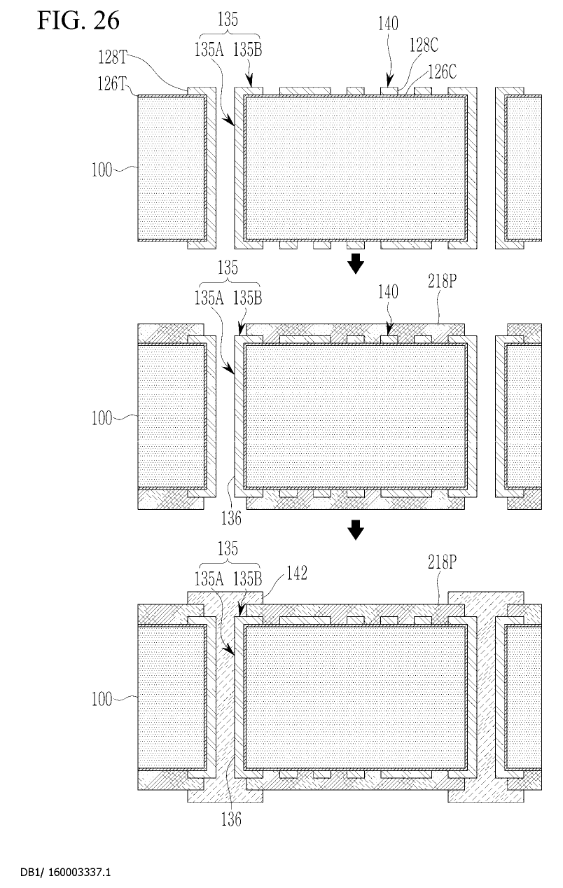

FIGS. 26 to 28 are process cross-sectional views for explaining a method of manufacturing a circuit board 20B according to still another embodiment.

In the method of manufacturing the circuit board described with reference to FIGS. 17 to 24, the first circuit layer 140 and the through-via 130 are formed to be distinguished from each other before forming the plug 132. That is, the seed layer 126 is patterned through flash etching before filling the interior of the hollow portion 131 of the through-via 130 with the preliminary plug 132P. In contrast, in the method of manufacturing the circuit board 20B according to this embodiment, the plug 142 may be formed before flash etching for patterning the seed layer 106, and the seed layer 106 may be patterned by flash etching together with the thus-formed plug 142.

Referring to FIG. 26, via holes 104 may be formed penetrating the first insulating layer 100, and a seed layer 126 may be formed by electroless plating on the inner walls of the via holes 104 and on the surface of the first insulating layer 100. An electroplating layer may be formed by performing electroplating after exposing the seed layer 126 of the via holes 104 and their surroundings, and the area where the first circuit layer 140 will be formed, using a first mask pattern.

The electroplating layer formed on the seed layer 126 on the inner walls of the via holes 104 may constitute the through-via 135 by connecting with the electroplating layer around the via holes 104. Specifically, the electroplating layer on the inner walls of the via holes 104 may form the through portion 135A of the through-via 135, and the electroplating layer around the via holes 104 may form the land portion 135B of the through-via 135 as the electroplating layer pattern 108T. Also, an electroplating layer pattern 128C may be formed in the area where the first circuit layer 140 will be formed.

Then, a second mask pattern 218P may be formed on the seed layer 126 and electroplating layer patterns 108T and 108C. The second mask pattern 218P may cover a portion of the electroplating layer pattern 108T that will constitute the land portion 115B of the through-via 115 and may expose a portion of the land portion 115B positioned along the hollow portion 116 of the through-via 115 and its edges. The second mask pattern 218P may be patterned by exposing and developing a photosensitive dry film.

Then, a preliminary plug 142P may be formed filling the interior of the hollow portion 116 of the through-via 115 and extending stepwise over the exposed land portion 115B and the second mask pattern 218P. That is, the preliminary plug 142P may be partially positioned on the land portion 115B exposed by the second mask pattern 218P and may be positioned along the opened edges of the second mask pattern 218P. The preliminary plug 142P may be formed by printing insulating ink.

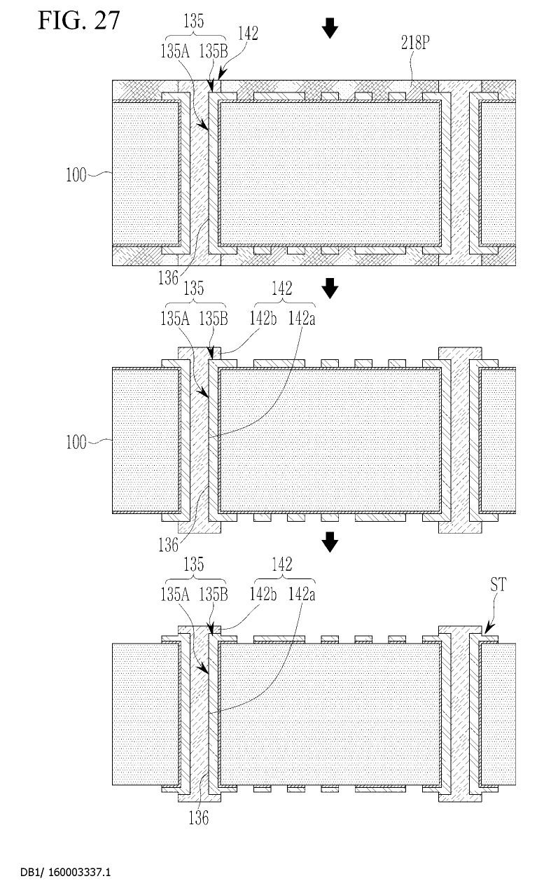

Referring to FIG. 27, the portion of the preliminary plug 142P formed on the second mask pattern 218P and the second mask pattern 218P may be polished together to planarize their surfaces. During this process, the portion of the preliminary plug 142P extending over the second mask pattern 218P may be removed to become the plug 142. Also, the thickness of the plug 142 portion positioned on the land portion 115B and the second mask pattern 218P may become smaller than before planarization, and the surfaces of the plug 142 and the second mask pattern 218P may be positioned substantially in the same plane. A portion of the plug 142 may be surrounded by the through portion 135A of the through-via 135 and may be formed including non-conductive material.

Then, when the remaining second mask pattern 218P is stripped and removed, a plug 142 may be formed filling the hollow portion 116 of the through-via 115 and protruding and extending over the land portion 115B. Therefore, the plug 142 may include a plug body 142a filling the hollow portion 116 of the through-via 115 penetrating in the first direction and protruding outward from the first insulating layer 100, and a plug head 142b extending from this plug body 142a in the second direction perpendicular to the first direction and disposed on the land portion 115B.

Then, after removing the second mask pattern 218P, the first circuit layer 140 and the through-via 135 may be formed by removing the exposed seed layer 126 and copper foil layer 102 through flash etching. The first circuit layer 140 may be formed on the first insulating layer 100 to include the seed layer pattern 126C and the electroplating layer pattern 128C. The through portion 135A of the through-via 135 may include the seed layer pattern 126T and the electroplating layer pattern 128T stacked on the inner wall surface of the via hole 104. The land portion 135B of the through-via 135 may include the seed layer pattern 126T and the electroplating layer pattern 128T stacked on the first insulating layer 100.

At least a portion of the plug head 142b may be positioned on the electroplating layer pattern 108T of the land portion 115B. During the flash etching process, a portion of the electroplating layer pattern 108T constituting the land portion 115B of the through-via 115 is exposed to the etching solution, but the portion of the electroplating layer pattern 108T covered by the plug head 142b may not be exposed to the etching solution. Therefore, the exposed portion of the electroplating layer pattern 108T may be etched to become lower than the unexposed portion. As a result, the electroplating layer pattern 108T of the land portion 115B may have a step difference ST on the surface facing the plug head 142b, and this step difference ST may have a side aligned with the edge of the plug head 142b.

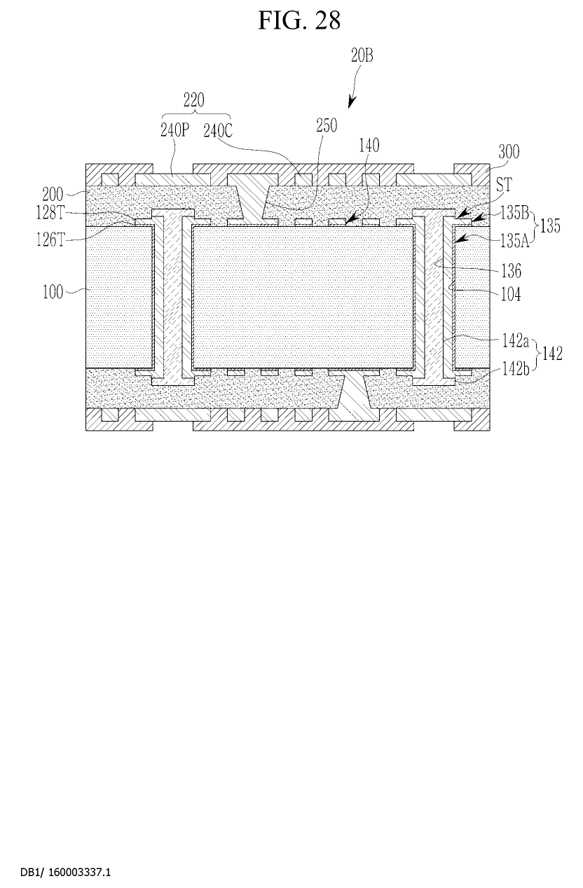

Referring to FIG. 28, a second insulating layer 200 may be formed on the first insulating layer 100 to embed the first circuit layer 140, land portion 135B of the through-via 135, and plug head 142b. Also, a second circuit layer 240 including connection pads 240P and circuit wiring 240C may be formed on the second insulating layer 200. Additionally, build-up vias 250 may be formed penetrating the second insulating layer 200 to connect the first circuit layer 140 and the second circuit layer 240. The second circuit layer 240 and build-up vias 250 may be formed by performing conventional wiring formation methods, for example, subtractive process, AP (Additive Process), SAP (Semi Additive Process), or MSAP (Modified Semi Additive Process).

A protective layer 300 exposing a portion of the connection pads 240P may be formed on the second insulating layer 200 on which the connection pads 240P and circuit wiring 240C of the second circuit layer 240 are formed. The protective layer 300 may be a solder resist layer formed by exposing and developing photosensitive resin. Thus, the circuit board 20B according to this embodiment may be completed.

While preferred embodiments of the present disclosure have been described above, the present disclosure is not limited thereto and may be variously modified and practiced in the scope of the claims, description of the disclosure, and accompanying drawings, and such modifications and variations are also naturally included in the scope of the present disclosure.

What is claimed is:

1. A circuit board comprising:
an insulating layer having a via hole penetrating in a first direction;
a through-via including:
a through portion configured to cover an inner wall of the via hole and having a hollow portion extending in the first direction, and
a land portion extending from the through portion in a second direction perpendicular to the first direction;
a circuit layer disposed on the insulating layer and spaced apart from the land portion of the through-via; and
a plug including:
a plug body filling the hollow portion of the through-via and protruding outward from a surface of the insulating layer, and
a plug head extending from the plug body in the second direction and disposed on the land portion.

2. The circuit board of claim 1, wherein
the plug head protrudes outward from a surface of the land portion.

3. The circuit board of claim 1, wherein
a diameter of the plug head in the second direction is smaller than a diameter of the land portion in the second direction.

4. The circuit board of claim 1, wherein
the land portion has a step on a surface facing the plug head.

5. The circuit board of claim 4, wherein
the step has a side aligned with an edge of the plug head.

6. The circuit board of claim 1, wherein
a number of metal layers in the through portion is less than a number of metal layers in the land portion.

7. The circuit board of claim 6, wherein
the through portion includes a seed layer pattern and an electroplating layer pattern sequentially stacked from an inner wall surface of the via hole, and the land portion includes a copper foil layer pattern, the seed layer pattern, and the electroplating layer pattern sequentially stacked on the insulating layer.

8. The circuit board of claim 7, wherein
the seed layer pattern is an electroless plating layer pattern.

9. The circuit board of claim 1, wherein
each of the circuit layer and the land portion includes a copper foil layer pattern, a seed layer pattern, and an electroplating layer pattern sequentially stacked on the insulating layer.

10. The circuit board of claim 1, wherein
a number of metal layers in the through portion is equal to a number of metal layers in the land portion.

11. The circuit board of claim 10, wherein
the through portion includes a seed layer pattern and an electroplating layer pattern sequentially stacked from an inner wall surface of the via hole, and the land portion includes the seed layer pattern and the electroplating layer pattern sequentially stacked on the insulating layer.

12. The circuit board of claim 11, wherein
the seed layer pattern is an electroless plating layer pattern.

13. The circuit board of claim 11, wherein
the seed layer pattern is a sputtering layer pattern.

14. The circuit board of claim 11, further comprising
a primer resin layer between the insulating layer and the seed layer pattern.

15. A method of manufacturing a circuit board, comprising:
forming a via hole penetrating a first insulating layer in a first direction;
forming a first seed layer on a surface of the first insulating layer in which the via hole is formed;
forming a first mask pattern on the first seed layer so as to expose the first seed layer of the via hole and an area surrounding the via hole;
forming an electroplating layer pattern on the first seed layer exposed by the first mask pattern to form a through-via having:
a hollow portion penetrating in the first direction,
and a land portion extending on the first insulating layer;forming a second mask pattern exposing the hollow portion of the through-via and at least a portion of the land portion of the through-via;
forming a preliminary plug filling the hollow portion of the through-via;
planarizing the preliminary plug and the second mask pattern; and
forming a plug by removing the second mask pattern remaining after the planarization.

16. The method of manufacturing the circuit board of claim 15, further comprising
forming a second insulating layer on the first insulating layer to embed the land portion of the through-via and the plug.

17. The method of manufacturing the circuit board of claim 15, wherein
forming the preliminary plug includes filling the hollow portion of the through-via with a non-conductive material.

18. The method of manufacturing the circuit board of claim 15, further comprising
forming a copper foil layer on the first insulating layer, wherein
the forming of the first seed layer includes forming the first seed layer on the copper foil layer.

19. The method of manufacturing the circuit board of claim 15, wherein
the forming of the first seed layer includes forming the first seed layer on the first insulating layer through sputtering or electroless plating.

20. The method of manufacturing the circuit board of claim 15, further comprising
forming a primer resin layer on the first insulating layer.
